(19) United States
(12) Patent Application Publication
(10) Pub. No.: US 2012/0050173 A1
(43) Pub. Date: Mar. 1, 2012

(54) INTEGRATED TOUCH PANEL AND MANUFACTURING METHOD THEREOF

(75) Inventors: SHIH-LIANG CHOU, TAO-YUAN (TW); HSUEH-CHIH CHIANG, TAO-YUAN (TW); CHIEN-MIN WENG, TAO-YUAN (TW); JYH-AN CHEN, TAO-YUAN (TW); SHR-LUNG CHEN, TAO-YUAN (TW); I-WEN LEE, CHUNG LI CITY (TW); HSING-YEH CHEN, CHUNG LI CITY (TW)

(73) Assignees: AVCT OPTICAL ELECTRONIC CO., LTD., CHUNG LI CITY (TW); APPLIED VACUUM COATING TECHNOLOGIES CO., LTD., TAO-YUAN (TW)

(21) Appl. No.: 12/870,063

(22) Filed: Aug. 27, 2010

(51) Int. Cl. G06F 3/041; C23C 14/34

(52) U.S. Cl. 345/173; 204/192.15

(57) ABSTRACT

The present invention proposes a surface capacitive integrated touch panel and manufacturing method thereof. The touch panel comprises a transparent substrate, an icon or artwork layer coated on the periphery of one side face of the transparent substrate, and the inner periphery of the icon layer is not perpendicular to the adjacent line of the transparent substrate. It also comprises a sensing layer which is stacked on icon layer or artwork layer and the areas on the transparent substrate uncovered with the icon layer or artwork layer. Other than that, it comprises a metal layout and an electrode pattern which are formed from the outer of the icon layer to its inner side. The electrode pattern is formed via coating, printing or spraying. This unconventional way of laminating the electrode pattern structures can effectively lower the overall thickness of the panel and increase yield rate.

### BACKGROUND OF THE INVENTION

1. Field of the Invention

The present invention is related to the touch panel technology, specifically in the invention of a surface capacitive integrated touch panel which is less thick and has higher yield rate.

2. Description of the Related Art

There are some common types of touch panels; i.e. the resistive panel, capacitive panel, surface acoustic wave panel, optical (infrared) panel etc. Among these, the most commonly used are the resistive panels, followed by the capacitive panels. The capacitive panels are further divided into 2 types; projected capacitive and surface capacitive. The advantages of the capacitive panels are waterproofing and scratch-proofing, and they have high light transmittance and broad temperature range. Therefore, the panels come at a high price. With the advancement of technology, however, the capacitive panels are beginning to gain a share in the market of small monitors.

The outermost surface of the conventional touch panel, which comes to contact with the environment, is usually made of a chemical-tempered cover glass substrate. This outermost cover substrate is then laminated to the sensing layer, which uses indium tin oxide (ITO) as its conductance. Integrating this combination with the display panel produces a complete touch screen. In the past, the cover glass substrate and the sensing layer described above are laminated with optically clear adhesive (OCA). Other than that, an additional black icon or artwork layer is printed on the peripheries of the cover glass substrate to shield the circuits. The conventional icon or artwork layer is printed on the cover glass substrate perpendicularly and this will usually cause unsatisfactory results when laminating the substrate to the sensing layer; incomplete or uneven cladding may occur. Many times, the uneven slots produced during the etching of sensing circuits on the ITO sensing layers will compromise the quality of the images on the display and reduce its yield rate. Moreover, in the conventional touch panels, electrode pattern is usually laminated on the sensing layers and this would increase the overall thickness of the panel. This is against the current market trend that prefers thin and slim products. The cost required to maintain a better yield is also higher.

In order to improve the poor outcome caused by the conventional OCA lamination process, the inventor invented an integrated touch panel which uses low temperature sputtering method to stack the films instead of OCA lamination. This will effectively reduce the thickness of the touch panel and thus increase the light transmittance efficiency. Furthermore, stacking optical film on the sensing layer with sputtering method has lesser problems of uneven slots caused by circuit etching and thus the quality of the images on the display is improved. Moreover, the placement of the icon layer is different from that in the conventional device and this will improve the cladding of the subsequent coatings remarkably and will get rid of the problems of uneven coatings all together. The overall strength of the panel is improved greatly. Directly coating, printing or spraying electrode pattern on the sensing layer also effectively caused the thickness of the panel to be reduced and the yield rate improved.

### SUMMARY OF THE INVENTION

In view of the abovementioned problems, the purpose of the present invention is to propose a whole new touch panel structure which operates on surface capacitance. In this new structure, the icon or artwork layer is coated on the periphery of one side face of the transparent substrate, and the inner periphery of the icon layer or artwork layer is not perpendicular to the adjacent line of the transparent substrate. Sputtering method is then used to stack layers of optical films or sensing layers on the above. As the icon layer is not placed perpendicularly, complete cladding of the optical films or sensing layers can be done and thus the yield rate of the device increased. The coating, printing or spraying of electrode pattern directly on the sensing layer also effectively caused the thickness of the panel to be reduced and the yield rate improved.

In order to achieve the above objectives, an integrated touch panel is introduced in the present invention. It consists of one transparent substrate, one icon or artwork layer coated on the periphery of one side face of the transparent substrate and its inner periphery is not perpendicular to the adjacent line of the transparent substrate. It also consists of one sensing layer stacked on the icon layer or artwork layer and the areas on the transparent substrate uncovered with the icon layer or artwork layer. Other than that, it consists of a metal layout located at the outer periphery of the sensing layer, corresponding to the mapping location of the icon layer or artwork layer. It also consists of an electrode pattern coated, printed, or sprayed directly on the inner periphery of the sensing layer, opposite position of the metal layout and corresponds to the mapping location of the icon layer or artwork layer. The integrated touch panel may further comprise a plurality of slots etched on the inner most periphery of the sensing layer, corresponding to the mapping location of the icon layer and opposite position of the electrode pattern. The transparent substrate may either be made of glass or polymer plastics.

In order to achieve the above objectives, an integrated touch panel is introduced in the present invention. It consists of one transparent substrate, one icon or artwork layer coated on the periphery of one side face of the transparent substrate and its inner periphery is not perpendicular to the adjacent line of the transparent substrate. It also consists of one optical film stacked on icon layer or artwork and the areas on the transparent substrate uncovered with the icon layer or artwork layer. Other than that, it consists of a sensing layer stacked on the optical film. It consists of a metal layout coated on the outer periphery of the sensing layer, corresponding to the mapping location of the icon layer or artwork layer. It consists of an electrode pattern coated, printed, or sprayed directly on the inner periphery of the sensing layer, opposite of the metal layout and corresponds to the mapping location of the icon layer or artwork layer. The integrated touch panel may further comprise several slots etched on the inner most periphery of the sensing layer, corresponding to the mapping location of the icon layer and opposite location of the electrode pattern. The transparent substrate may either be made of glass or polymer plastics.

In order to achieve the above objectives, the present invention proposes a production method for the abovementioned integrated touch panel. The temperature of the entire production process has to be controlled below 200□. The production steps include cutting to form a plurality if transparent substrates and coating an icon layer on the periphery of each transparent substrate. The inner periphery of each icon layer is not perpendicular to the adjacent line of such transparent substrate. A sensing layer is coated via sputtering method on each icon layer or artwork layer and the areas on the transparent substrate uncovered with icon layer or artwork layer. A metal layout is coated on the outer periphery of the sensing layer, corresponding to the mapping location of the icon layer or artwork layer. An electrode pattern is formed at the inner periphery of the sensing layers, corresponding to the mapping location of the icon layer and opposite location of the metal layout.

One of the advantages of the present invention is that instead of using the conventional way of laminating the transparent substrate and sensing layer with optically clear adhesive, the inner periphery of the icon layer or artwork layer is arranged not perpendicular to the adjacent line of the transparent substrate so that complete cladding of the optical film or sensing layer can be done via sputtering method. The yield of the structure is thus raised. At the same time, one side face of the sensing layer is covered with optical film to cover up the slots caused by circuit etching preventing them from reducing the resolution and impairing the visual quality of the touch panel. The coating, printing or spraying of electrode pattern directly on the sensing layer also effectively caused the thickness of the panel to be reduced and the yield rate improved.

### BRIEF DESCRIPTION OF THE DRAWINGS

FIG. 1 is an exploded diagram in accordance with the preferred embodiment of the present invention;

FIG. 2 is a cross sectional view in accordance with the preferred embodiment of the present invention;

FIG. 3 is a cross sectional view in accordance with the preferred embodiment of the Present Invention with an additional passivation film;

FIG. 4 is a cross sectional view in accordance with the preferred embodiment of the present invention;

FIG. 5 is a cross sectional view in accordance with the preferred embodiment of the present invention with an additional passivation film; and

FIG. 6 is a flow chart of the manufacturing process for the integrated touch panel in accordance with the present invention.

### DETAILED DESCRIPTION OF THE PREFERRED EMBODIMENTS

The descriptions of the drawings are given below so that the certification committee will have a clear idea of the subject matter of the present invention. Please refer to the drawings and their respective descriptions.

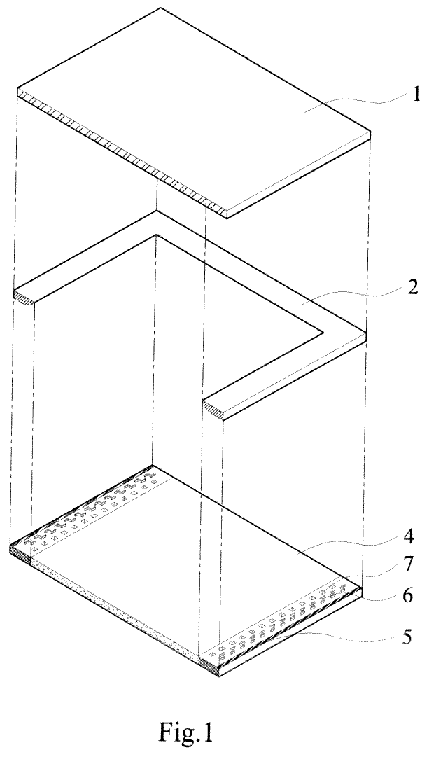

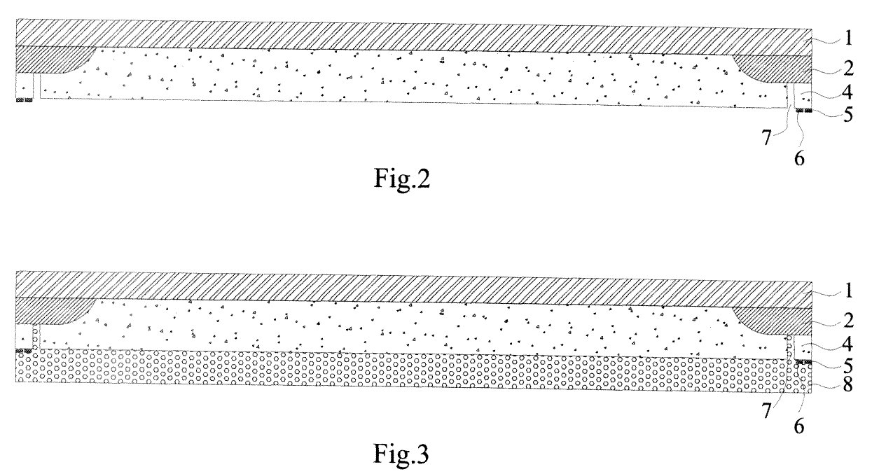

Please refer to the first (FIG. 1) and second (FIG. 2) drawings which are the exploded diagram and cross sectional view of the preferred embodiment of the present invention respectively. First of all, when manufacturing the integrated touch panel, the temperature of the entire production process has to be controlled below 200□. The diagram shows the structure of an integrated touch panel. Combining a display panel (not shown in the drawing) with it will create a complete panel. It is mainly a surface capacitive touch panel. The integrated touch panel comprises a transparent substrate 1, an icon layer or artwork layer 2, a sensing layer 4, a metal layout 5, and an electrode pattern 6.

The transparent substrate 1 is the outermost surface of the touch panel that directly comes to contact with the environment. Therefore, it is strengthened to protect it from scratch and other damages. The transparent substrate 1 may either be made of glass or polymer plastic. If glass is used as its material, the glass is first cut into several small pieces where the thickness of each is about 0.5˜3.5 mm. These little pieces are then chemically-tempered by dipping them in potassium nitrate solution or other chemical solutions.

The icon layer or artwork layer 2 mainly functions as a shield to cover up the signal conducting wires at the edges of the touch panel. To do that, ink prints of about 2-15 μm thick are coated on the periphery of one side face of the transparent substrate 1. Also, the inner periphery of the icon layer or artwork layer 2 is not perpendicular to the adjacent line of the transparent substrate 1 so that the cladding of the subsequent structures can be complete. In order to control the screen printings so that they are formed at a non-perpendicular angle, the below parameters are required: ink with a viscosity of 10˜300 dPa·s, the screen conditioned at 50˜400 mesh tetron screen, and the tension at minimum 15 Newton force.

The sensing layer 4 is made of conductive materials like the ITO transparent conductive film with a thickness of 10-100 nm. This layer is stacked on the icon layer or artwork layer 2 and areas on the transparent substrate 1 uncoated with the icon layer or artwork layer 2. This can be done using vacuum DC and RF magnetron sputtering deposition technique. Otherwise, methods like layer-by-layer sputtering, spray pyrolysis, pulsed laser deposition, arc discharge ion plating, reactive evaporation, ion beam sputtering, or chemical vapor deposition (CVD) etc. can be used.

The function of metal layout 5 is to provide voltage so that a steady electric field distribution is created within the touch panel. It is usually made of silver and printed on the ITO. The metal layout is placed at the outermost periphery of the sensing layer 4, corresponding to the mapping location of the icon layer or artwork layer 2. This location allowed the silver lines to be covered by the icon layer or artwork layer 2 and shielded from sight after the final assembly of the panel is completed. The outlook of the panel is thus not affected. The electrode pattern 6 is placed at the inner periphery of the icon layer or artwork layer 2 in corresponding to the location of the metal layout 5, and formed via direct coating, printing, or spraying on the icon layer or artwork layer 2. As the electrode pattern 6 is directly formed on top of sensing layer 4, the overall thickness of the panel can be reduced, the quality controlled, and the yield rate improved. In order to produce an even distribution of electric field lines in the touch panel, several slots 7 are etched at the inner most periphery of the sensing layer 4, corresponding to the mapping location of the icon layer or artwork layer 2 and opposite location of the electrode pattern 6. With metal layout 5, electrode pattern 6, and slots 7, electric field distribution made of several X axis or Y axis is created in the touch areas of the touch panel. When the user touches the panel, touch signals are produced in the control circuits and transmitted to a host computer so that the touch orders and locations can be determined.

Please also refer to the third drawing (FIG. 3). It shows the cross section of the preferred embodiment of the present invention added with passivation film. This structure is not yet combined with display panel and constitutes only the touch panel. A passivation film 8 may be added on this touch panel prior to combining it with the display panel to protect the integrated touch panel from scratch and damages during combination. The passivation film may be formed via printing, spraying, or coating, and its final thickness is less than 20 μm. Other than that, this embodiment may further comprise a shield (not shown in the drawing) to block electromagnetic signal interferences from other sources. The shield may be formed via sputtering method and its thickness is around 10-100 nm.

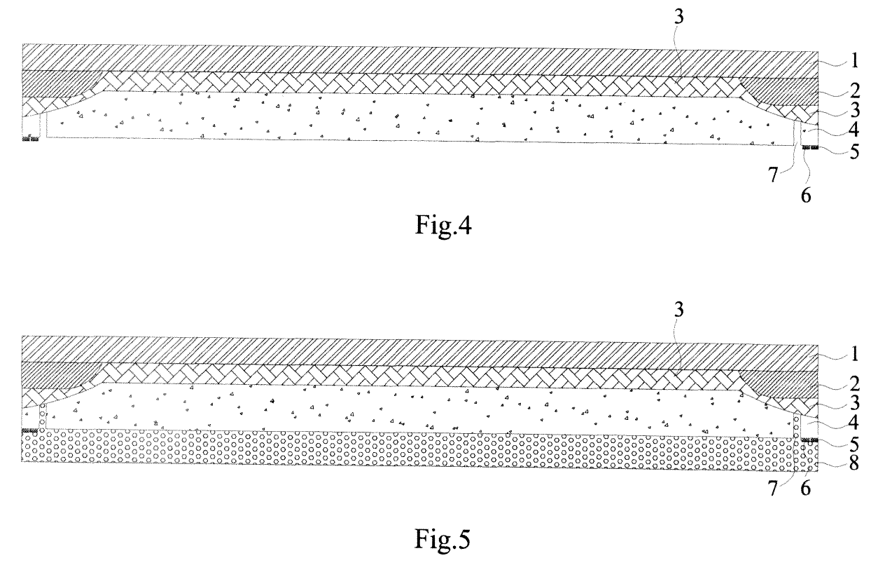

Please refer to the fourth (FIG. 4) and fifth (FIG. 5) drawings. FIG. 4 shows the cross section of one of the preferred embodiments of the present invention and FIG. 5 shows the cross section of a preferred embodiment added with passivation film. The structures of these two embodiments are rather similar to that of the abovementioned embodiments. The difference is that in the present preferred embodiments, one side face of the sensing layer 4 is coated with an optical film 3 which covers the icon layer or artwork layer 2 and other optical film 3 areas uncoated with the icon layer or artwork layer 2. This optical film 3 will minimize visual impairments caused by the uneven circuit slots 7 on the sensing layer 4 produced during circuit etching. The optical film 3 is placed on one side face of the sensing layer 4 via sputtering, spraying, or coating methods. Its thickness is less than 200 nm. Other structures of the embodiment are similar to that of the above-mentioned embodiments, and as such, are not repeated here.

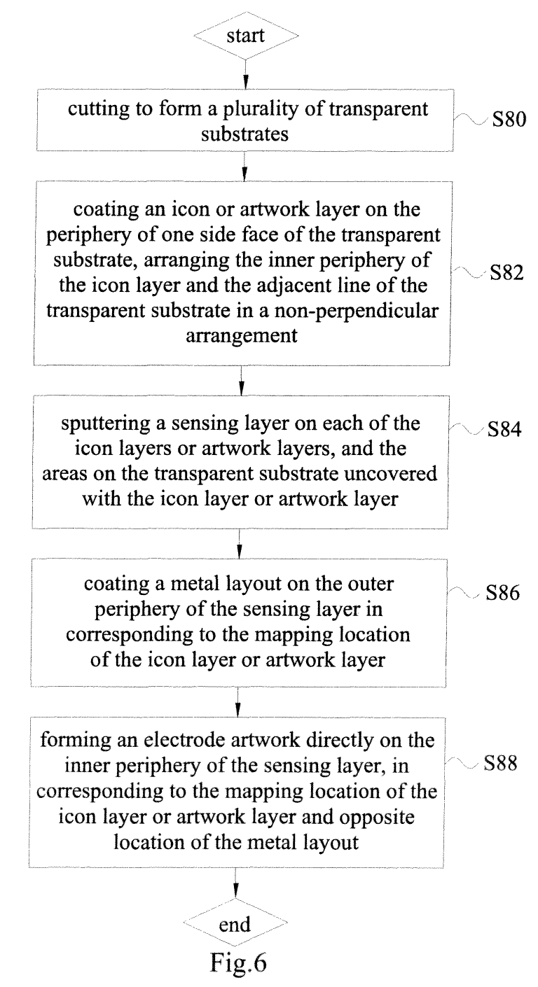

Please refer to the sixth drawing (FIG. 6). FIG. 6 is the flow chart of the manufacturing method for the integrated touch panel of the present invention. The flow chart shows the manufacturing method of the integrated touch panel shown in FIG. 2. First and foremost, the temperature of the entire production process is maintained below 200□. A big piece of transparent substrate like a glass substrate is cut to form a plurality of transparent substrates (S80). Cutting of the substrate may be carried out with CNC cutters, contour cutters, and laser cutters, etc. Strengthening of the substrates is then carried out by dipping them into chemical solutions like potassium nitrate solutions and so on to increase their strength.

Subsequently, an icon layer or artwork layer is coated on the periphery of one side face of each transparent substrate and the inner periphery of the icon layer is not perpendicular to the adjacent line of the transparent substrate (S82). In order to achieve that, the viscosity of the ink should be within 10˜300 dPa·s, the screen conditioned at 50˜400 mesh tetron screen, and the tension at minimum 15 Newton force. The final thickness of the film is around 2˜15 um.

A sensing layer is then sputtered on each icon layer or artwork layer and the areas on the transparent substrate uncovered with the icon layer or art work layer (S84). In order to minimize the visual impairment caused by uneven circuit slots on the sensing layer produced during circuit etching, an optical film may be sputtered on the icon layer or artwork layer and areas on the transparent substrate uncoated with the icon layer or artwork layer prior to the formation of the sensing layer. This will greatly reduce the visual impairment caused by the uneven slots produced during circuit etching. Coating the sensing layer directly on the icon layer or artwork layer and areas on the transparent substrate uncoated with the icon layer or artwork layer without adding the optical film will certainly not affect the embodiment of the present invention.

Lastly, in order to create power distribution lines in the touch areas for determination and implementation of touch orders, one metal layout is coated on the outer periphery of the sensing layer (S86), corresponding to the mapping location of the icon layer or artwork layer. An electrode pattern is then formed directly on the inner periphery of the sensing layer, corresponding to the mapping location of the icon layer or artwork layer and opposite of the metal layout (S88). Such addition enables the achievement of the above purposes.

Overall, the present invention avoids the conventional method of laminating the substrate and the sensing layers with optically clear adhesive. Instead, the inner periphery of the icon layer or artwork layer is not perpendicular to the adjacent line of the transparent substrate so that complete cladding can be obtained when sputtering the optical film or sensing layers on it. This overcomes the unevenness produced when the black icon layer or artwork layer is printed prior to film coating. The yield of the overall structure is thus raised. Furthermore, the quality of the ink used in film coating the icon layer or artwork layer will not deteriorate and so the resistive value of the ITO sensing layer will not alter. Meanwhile, one layer or two layers of optical film are stacked on top and/or bottom of each sensing layer to shield any slots caused by circuit etching. This will prevent the reduction of resolution and the impairment of visual quality. The coating, printing or spraying of electrode pattern directly on the sensing layer also effectively caused the thickness of the panel to be reduced and the yield rate improved. In conclusion, the integrated touch panel of the present invention has advantages of reduced thickness, simplified manufacturing process, increased yield rate, and less production cost.

All the above-mentioned are only applicable to the preferred embodiment of the present invention and will not restrict the scope of the actual embodiment of the present invention. As such, all equivalent or slightly modified versions produced by those familiar with the technology mentioned here will be considered the patent claim of the present invention in the event that such modification is found to be consistent with the essence and claims of the present invention.

What is claimed is:

1. An integrated touch panel, comprising:
a transparent substrate;
one of an icon or artwork layer coated on the periphery of one side face of the transparent substrate, and the inner periphery of the icon layer or artwork layer and the adjacent line of the transparent substrate being in a non-perpendicular arrangement;
a sensing layer stacked on the icon layer or artwork layer and the areas on the transparent substrate uncovered with the icon layer or artwork layer;
a metal layout coated on the outer periphery of the sensing layer in corresponding to the mapping location of the icon layer or artwork layer; and
an electrode pattern being at a position in corresponding to the mapping location of the icon layer or artwork layer and opposite position of metal layout, and disposed on the inner periphery of the sensing layer by coating, printing or sputtering.

2. The integrated touch panel as cited in claim 1, further comprising a plurality of slots etched on the inner most periphery of the sensing layer corresponding to the mapping location of the icon layer and the opposite position of the electrode pattern.

3. The integrated touch panel as cited in claim 2, further comprising a passivation film stacked on the metal layout and the electrode pattern, and filled on the top of the slots.

4. The integrated touch panel as cited in claim 3, further comprising a layer of shield disposed on one side face of the passivation film.

5. The integrated touch panel as cited in claim 1, wherein the transparent substrate is either made of glass or polymer plastics.

6. The integrated touch panel as cited in claim 2, wherein the transparent substrate is either made of glass or polymer plastics.

7. An integrated touch panel, comprising:
a transparent substrate;
an icon or artwork layer coated on the periphery of one side face of the transparent substrate, and the inner periphery of the icon layer and the adjacent line of the transparent substrate being in a non-perpendicular arrangement;
an optical film stacked on the icon layer and the areas on the transparent substrate uncovered with the icon layer;
a sensing layer stacked on the optical film;
a metal layout being in a position corresponding to the mapping location of the icon layer or artwork layer and coated on the outer periphery of the sensing layer; and
an electrode pattern being in a position corresponding to the mapping location of the icon layer or artwork layer and opposite position of metal layout, and disposed on the inner periphery of the sensing layer by coating, printing or sputtering.

8. The integrated touch panel as cited in claim 7, further comprising a plurality of slots etched on the inner most periphery of the sensing layer, and being in a position corresponding to the mapping location of the icon layer and opposite location of the electrode pattern.

9. The integrated touch panel as cited in claim 8, further comprising a passivation film stacked on the metal layout and electrode pattern, and filled on the top of the slots.

10. The integrated touch panel as cited in claim 9, further comprising a layer of shield stacked on one side face of the passivation film.

11. The integrated touch panel as cited in claim 7, wherein the transparent substrate is either made of glass or polymer plastics.

12. The integrated touch panel as cited in claim 8, wherein the transparent substrate is either made of glass or polymer plastics.

13. A manufacturing method for an integrated touch panel, the integrated touch panel comprising a transparent substrate, one of an icon or artwork layer coated on the periphery of one side face of the transparent substrate, and the inner periphery of the icon layer or artwork layer and the adjacent line of the transparent substrate being in a non-perpendicular arrangement, a sensing layer stacked on the icon layer or artwork layer and the areas on the transparent substrate uncovered with the icon layer or artwork layer, a metal layout coated on the outer periphery of the sensing layer in corresponding to the mapping location of the icon layer or artwork layer, and an electrode pattern being at a position in corresponding to the mapping location of the icon layer or artwork layer and opposite position of metal layout and disposed on the inner periphery of the sensing layer by coating, printing or sputtering, the temperature being controlled below 200° C. during the entire process, the method comprising steps of:
cutting to form a plurality of the transparent substrates;
coating icon layers or artwork layers on the peripheries of side faces of the transparent substrates, arranging the inner periphery of each of the icon layer or artwork layer and the adjacent line of the transparent substrate in a non-perpendicular arrangement;
sputtering a sensing layer on each of the icon layers or artwork layers, and the areas on the transparent substrate uncovered with the icon layers or artwork layers;
coating a metal layout on the outer periphery of the sensing layer in corresponding to the mapping location of the icon layer or artwork layer; and
forming an electrode pattern directly on the inner periphery of the sensing layer in corresponding to the mapping location of the icon layer or artwork layer and opposite location of the metal layout.
